(19) United States
(12) Patent Application Publication
(10) Pub. No.: US 2024/0040276 A1
(43) Pub. Date: Feb. 1, 2024

(54) IMAGE SENSOR AND OPERATION METHOD THEREOF

(71) Applicant: Samsung Electronics Co., Ltd., Suwon-si (KR)

(72) Inventor: Eun Sub SHIM, Suwon-si (KR)

(73) Assignee: Samsung Electronics Co., Ltd., Suwon-si (KR)

(21) Appl. No.: 18/310,750

(22) Filed: May 2, 2023

(30) Foreign Application Priority Data
Jul. 26, 2022 (KR) 10-2022-0092773

(51) Int. Cl. H04N 25/531; H04N 25/533; H04N 25/77

(52) U.S. Cl. CPC H04N 25/531; H04N 25/533; H04N 25/77

(57) ABSTRACT

Disclosed is an image sensor including a plurality of first pixels arranged in a first row and configured to generate first charges in response to a first exposure and a plurality of second pixels arranged in a second row different from the first row and configured to generate second charges in response to a second exposure. At least one pixel of the plurality of first pixels includes a photo diode, a first floating diffusion, a first transfer transistor, a gate electrode of the first transfer transistor partially overlapping the first floating diffusion area when viewed in a horizontal direction, a second floating diffusion area spaced apart from the first floating diffusion area, one end of the second floating diffusion area being connected to a gate of a drive transistor, and a second transfer transistor that electrically connects the first floating diffusion area to the second floating diffusion area.

### CROSS-REFERENCE TO RELATED APPLICATIONS

This application claims priority under 35 U.S.C. § 119 to Korean Patent Application No. 10-2022-0092773 filed on Jul. 26, 2022, in the Korean Intellectual Property Office, the disclosure of which is incorporated by reference herein in its entirety.

### BACKGROUND

Example embodiments of the present disclosure described herein relate to an image sensor.

An image sensor is a device that converts an optical image into an electrical signal. Nowadays, with the development of computer and communication industries, there is an increasing demand on a high-performance image sensor in various electronic devices such as a digital camera, a camcorder, a personal communication system (PCS), a game console, a security camera, a medical micro camera, a robot, and the like.

The image sensor includes a plurality of pixels. The plurality of pixels are arranged in a matrix with a row direction and a column direction. One image frame is generated by combining data generated from each of (or alternatively, at least one of) a plurality of pixels of an image sensor module. Because there are dozens of pixels to tens of millions of pixels included in the image sensor module, various sensing schemes have been developed to efficiently receive data from these pixels and to generate an image frame based on the received data. For example, the sensing schemes may include a global shutter scheme in which all pixels are simultaneously or contemporaneously sensed, a flutter shutter scheme in which all pixels are simultaneously or contemporaneously sensed and an exposure time is adjusted, a rolling shutter scheme in which pixels are controlled in units of row, a coded rolling shutter scheme, or the like.

### SUMMARY

Some example embodiments of the present disclosure provide an image sensor capable of moving charges, which are generated by a photo diode, in a direction of a node, at which a sensing operation is performed, without loss or with reduced loss.

An example embodiment provides An image sensor including a plurality of first pixels arranged in a first row and configured to generate first charges in response to a first exposure and a plurality of second pixels arranged in a second row different from the first row and configured to generate second charges in response to a second exposure. The at least one pixel of the plurality of first pixels includes a photo diode configured to generate the first charges in response to the first exposure to an incident light, a first floating diffusion area configured to store the first charges generated by the photo diode, a first transfer transistor configured to electrically connect the photo diode to the first floating diffusion area in response to a first transmission signal, wherein a gate electrode of the first transfer transistor at least partially overlaps the first floating diffusion area in a horizontal direction, a second floating diffusion area spaced apart from the first floating diffusion area, wherein one end of the second floating diffusion area is electrically connected to a gate of a drive transistor, and a second transfer transistor configured to electrically connect the first floating diffusion area to the second floating diffusion area in response to a second transmission signal.

An example embodiment provides an operating method of an image sensor operating in a rolling shutter scheme, the method including delivering charges generated by a photo diode to a first floating diffusion area, which overlaps a gate electrode of a first transfer transistor in a horizontal direction, by turning on the first transfer transistor, while the first transfer transistor is turned on, sharing the charges stored in the first floating diffusion area with a second floating diffusion area by turning on a second transfer transistor, moving the charges stored in the first floating diffusion area and the second floating diffusion area to the second transfer transistor by turning off the first transfer transistor, moving the charges stored in the second transfer transistor to the second floating diffusion area by turning off the second transfer transistor, and sampling a voltage level of the second floating diffusion area.

An example embodiment provides an operating method of an image sensor operating in a rolling shutter scheme, the method comprising electrically connecting a first floating diffusion area and a second floating diffusion area by turning on a second transfer transistor, while the second transfer transistor is turned on, delivering charges generated by a photo diode to the first floating diffusion area and the second floating diffusion area, which are electrically connected to each other by turning on a first transfer transistor, while the second transfer transistor is turned on, turning off the first transfer transistor, and sampling a voltage level of the first floating diffusion area and the second floating diffusion area, which are electrically connected to each other.

### BRIEF DESCRIPTION OF THE FIGURES

The above and other objects and features of the present disclosure will become apparent by describing in detail embodiments thereof with reference to the accompanying drawings.

FIG. 1 is a block diagram illustrating an image sensor, according to an embodiment of the present disclosure.

FIG. 2 is a circuit diagram illustrating a unit pixel 112, according to an embodiment of the present disclosure.

FIG. 3 is a plan view illustrating an example of an area ‘A’ of FIG. 2.

FIG. 4 is a cross-sectional view illustrating the area ‘A’ of FIG. 3 taken along line I-I′.

FIG. 5 is a diagram showing an operating method of the pixel array of FIG. 1.

FIG. 6 is a timing diagram illustrating a readout operation of the unit pixel of FIG. 2.

FIGS. 7A-E are diagrams illustrating a potential state of the unit pixel of FIG. 2.

FIG. 8 is a timing diagram illustrating another example of a readout operation of the unit pixel of FIG. 2.

FIGS. 9A-B are diagrams illustrating a potential state of a unit pixel according to the readout operation of FIG. 8.

FIG. 10 is a timing diagram illustrating another example of a readout operation of the unit pixel of FIG. 2.

FIG. 11 is a timing diagram illustrating another example of a readout operation of the unit pixel of FIG. 2.

FIG. 12 is a timing diagram illustrating a readout operation of the unit pixel of FIG. 2.

FIGS. 13A-C are diagrams illustrating a potential state of the unit pixel of FIG. 2.

FIG. 14 is a timing diagram illustrating a readout operation of the unit pixel of FIG. 2.

FIG. 15A-B are diagrams illustrating a potential state of the unit pixel of FIG. 2.

FIGS. 16, 17 and 18 are cross-sectional views illustrating various examples of area ‘A’ of FIG. 2.

FIGS. 19A-C are diagrams for describing a unit pixel 112_1, according to another embodiment of the present disclosure.

FIG. 20 is a circuit diagram illustrating a unit pixel 112_2, according to another embodiment of the present disclosure.

FIGS. 21 and 22 are circuit diagrams illustrating unit pixels 112_3 and 112_4, according to an embodiment of the present disclosure.

### DETAILED DESCRIPTION

Hereinafter, embodiments of the present disclosure may be described in detail and clearly to such an extent that an ordinary one in the art easily implements the present disclosure.

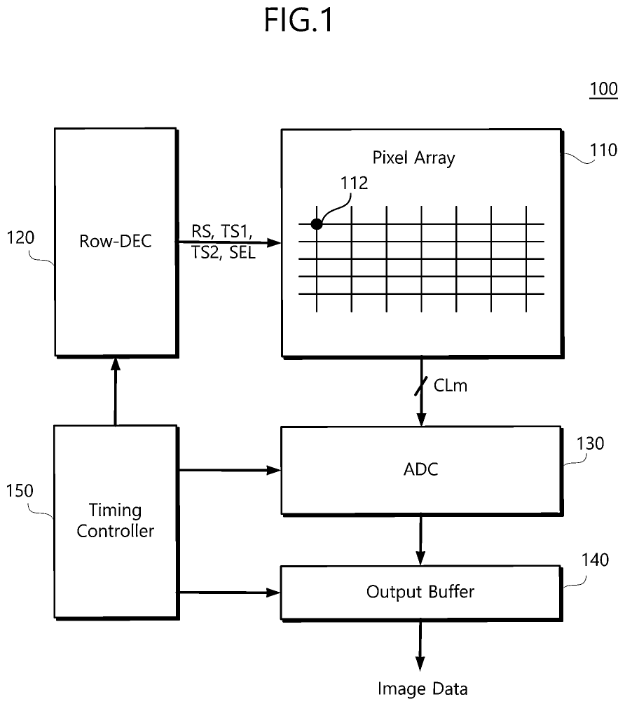

FIG. 1 is a block diagram illustrating an image sensor, according to an embodiment of the present disclosure. Referring to FIG. 1, an image sensor 100 may include a pixel array 110, a row decoder 120, an analog-to-digital converter (ADC) 130, an output buffer 140, and a timing controller 150.

The pixel array 110 includes a plurality of unit pixels 112. For example, the plurality of unit pixels 112 may be arranged in a matrix form. The pixel array 110 may receive pixel driving signals such as a selection signal SEL, a reset signal RS, and transmission signals TS1 and TS2 from the row decoder 120. The pixel array 110 operates under the control of the received pixel driving signals, and each of (or alternatively, at least one of) the unit pixels 112 may convert an optical signal into an electrical signal. Moreover, the electrical signal generated by each of (or alternatively, at least one of) the unit pixels 112 may be provided to the analog-to-digital converter 130 through a plurality of column lines CLm.

Each of (or alternatively, at least one of) the plurality of unit pixels 112 included in the pixel array 110 may include first and second floating diffusion areas spaced from each other. A first transfer transistor may be positioned between a photo diode and the first floating diffusion area to connect or block the photo diode and the first floating diffusion area with or from each other in response to the first transmission signal TS1. A second transfer transistor may be positioned between the first floating diffusion area and the second floating diffusion area to connect or block the first floating diffusion area and the second floating diffusion area with or from each other in response to the second transmission signal TS2.

In an embodiment of the present disclosure, a gate electrode of the first transfer transistor may be formed to overlap the first floating diffusion area when viewed in a horizontal direction. An overlap capacitor may be generated between the gate electrode of the first transfer transistor and the first floating diffusion area, and the gate electrode of the first transfer transistor and the first floating diffusion area may be strongly coupled. Accordingly, when a voltage level of the gate electrode of the first transfer transistor changes, a voltage level of the first floating diffusion area also changes.

In particular, when charges generated by a photo diode move in a direction of a node where a sensing operation is performed, the first transfer transistor according to an embodiment of the present disclosure may be turned off before the second transfer transistor. Accordingly, an asymmetric potential structure, in which a voltage level of the node where the sensing operation is performed is relatively high, is formed, and thus charges may move in the direction of the node where the sensing operation is performed without loss or with reduced loss. According to an embodiment of the present disclosure, a structure and an operation of each of (or alternatively, at least one of) the unit pixels 112 will be more fully described with reference to drawings below.

Continuing to refer to FIG. 1, the row decoder 120 may select one of rows of the pixel array 110 under control of the timing controller 150. To select one of a plurality of rows, the row decoder 120 may generate the selection signal SEL. Moreover, the row decoder 120 may activate the reset signal RS, the first and second transmission signals TS1 and TS2 for unit pixels corresponding to the selected row depending on a predetermined or desired order. Afterward, a reset level signal, a sensing signal, and the like, which are generated from each of (or alternatively, at least one of) the unit pixels 112 in the selected row, may be delivered to the analog-to-digital converter 130.

The analog-to-digital converter 130 may convert the reset level signal and the sensing signal into a digital signal and may output the digital signal. For example, the analog-to-digital converter 130 may sample the reset level signal and the sensing signal in a correlated double sampling manner and may then convert the sampled result into a digital signal. To this end, a correlated double sampler (CDS) may be further included in front of the analog-to-digital converter 130.

The output buffer 140 may latch and output image data provided from the analog-to-digital converter 130 in units of column. The output buffer 140 may temporarily store image data output from the analog-to-digital converter 130 under control of the timing controller 150 and may then output the latched (or temporarily stored) image data sequentially by a column decoder.

The timing controller 150 may control the pixel array 110, the row decoder 120, the analog-to-digital converter 130, the output buffer 140, and the like. To perform operations of the pixel array 110, the row decoder 120, the analog-to-digital converter 130, the output buffer 140, and the like, the timing controller 150 may supply control signals, such as clock signals and timing control signals. The timing controller 150 may include a logic control circuit, a phase locked loop (PLL) circuit, a timing control circuit, a communication interface circuit, and the like.

The configuration of the image sensor 100 according to some example embodiments of the present disclosure is briefly described above. According to some example embodiments of the present disclosure, each of (or alternatively, at least one of) the unit pixels 112 constituting the pixel array 110 includes the first and second floating diffusion areas spaced from each other. A first transfer transistor may electrically connect the photo diode to the first floating diffusion area, and a second transfer transistor may electrically connect the first floating diffusion area to the second floating diffusion area. In particular, the gate electrode of the first transfer transistor may overlap the first floating diffusion area when viewed in a horizontal direction, and thus the asymmetric potential structure in which charges capable of moving to a node where a sensing operation is performed may be formed. As a result, charges generated by a photo diode may move to the node where the sensing operation is performed without loss or with reduced loss, and thus the image quality of the image sensor 100 may be improved.

[Image Sensor Supporting High Conversion Gain]

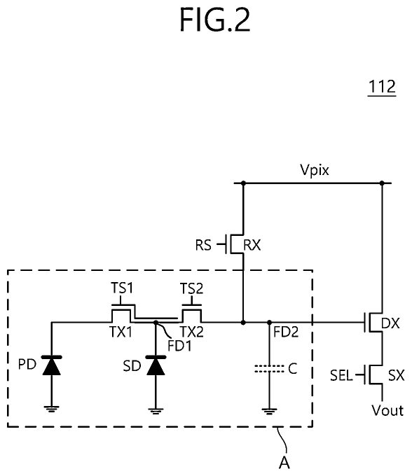

FIG. 2 is a circuit diagram illustrating the unit pixel 112, according to some example embodiments of the present disclosure.

The unit pixel 112 according to some example embodiments of the present disclosure may provide a high conversion gain (HCG). That is, in a low illumination mode, the unit pixel 112 according to some example embodiments of the present disclosure may form an asymmetric potential structure through coupling between a gate electrode TG1 of a first transfer transistor TX1 and a first floating diffusion area FD1, and thus charges generated by a photo diode PD may move to a second floating diffusion area FD2 without loss or with reduced loss. To this end, the gate electrode TG1 of the first transfer transistor TX1 may overlap the first floating diffusion area FD1 when viewed in a horizontal direction.

Referring to FIG. 2, the unit pixel 112 may include the single photo diode PD and five NMOS transistors TX1, TX2, RX, DX, and SX.

The photo diode PD may be a photosensitive element that generates and accumulates charges depending on the amount of incident light or the intensity of light. The photo diode PD may be implemented as a photo transistor, a photo gate, a pinned photo diode (PPD), an organic photo diode (OPD), a quantum dot (QD), or the like.

The first transfer transistor TX1 may be turned on or off in response to the first transmission signal TS1 provided from the row decoder 120 and may transmit charges accumulated in the photo diode PD to the first floating diffusion area FD1.

The second transfer transistor TX2 is positioned between the first floating diffusion area FD1 and the second floating diffusion area FD2. The second transfer transistor TX2 may electrically connect or block the first floating diffusion area FD1 and the second floating diffusion area FD2 with or from each other in response to the second transmission signal TS2.

A floating diffusion area may include the first floating diffusion area FD1 and the second floating diffusion area FD2 that are separated from each other. One end of the first floating diffusion area FD1 may correspond to a drain of the first transfer transistor TX1, and the other end thereof may correspond to a source of the second transfer transistor TX2. One end of the second floating diffusion area FD2 may correspond to a drain of the second transfer transistor TX2. The other end thereof may be connected to a gate of the drive transistor DX driven as a source follower amplifier.

The gate electrode TG1 of the first transfer transistor TX1 may overlap the first floating diffusion area FD1 when viewed in a horizontal direction. Accordingly, the first floating diffusion area FD1 may be coupled to the gate electrode TG1 of the first transfer transistor TX1. Accordingly, as a voltage level of the gate electrode TG1 of the first transfer transistor TX1 increases or decreases, a voltage level of the first floating diffusion area FD1 may also increase or decrease. That is, the asymmetric potential structure in which charges generated by the photo diode PD are capable of moving to the second floating diffusion area FD2, where a sampling operation is performed, without loss or with reduced loss may be formed by controlling the voltage level of the first floating diffusion area FD1.

For example, when a high-level voltage is provided to the gate electrode TG1 of the first transfer transistor TX1 to turn on the first transfer transistor TX1, the voltage level of the first floating diffusion area FD1 may also increase. In this case, the asymmetric potential structure in which charges stored in the photo diode PD are capable of moving to the first floating diffusion area FD1 without loss or with reduced loss may be formed.

For example, when a low-level voltage is provided to the gate electrode TG1 of the first transfer transistor TX1 to turn off the first transfer transistor TX1, the voltage level of the first floating diffusion area FD1 may also decrease. In this case, the voltage level of the first floating diffusion area FD1 may be lower than the voltage level of the second floating diffusion area FD2, and thus the asymmetric potential structure in which charges capable of moving from the first floating diffusion area FD1 to the second floating diffusion area FD2 without loss or with reduced loss may be formed.

The reset transistor RX may reset the first and second floating diffusion areas FD1 and FD2 in response to the reset signal RS. For example, as illustrated in FIG. 2, a source of the reset transistor RX may be connected to the second floating diffusion area FD2. When the reset signal RS is activated while the second transmission signal TS2 is activated, the reset transistor RX is turned on, and a power supply voltage Vpix is delivered to the first and second floating diffusion areas FD1 and FD2. In this case, charges accumulated in the first and second floating diffusion areas FD1 and FD2 may be drained to a terminal of the power supply voltage Vpix, and voltages of the first and second floating diffusion areas FD1 and FD2 may be reset to a level of the power supply voltage Vpix.

In the meantime, FIG. 2 illustrates that the reset transistor RX is connected to the second floating diffusion area FD2, but is not limited thereto. For example, the reset transistor RX may be connected to the first floating diffusion area FD1.

A gate of the drive transistor DX may be connected to the second floating diffusion area FD2, and may serve as a source follower amplifier. For example, the drive transistor DX may amplify a change in an electrical potential of the second floating diffusion area FD2 and may deliver the amplified change to a column line CLi via the selection transistor SX.

The selection transistor SX is used to select a unit pixel to be read in units of row. The selection transistor SX may be driven in response to the selection signal SEL provided in units of row. When the selection transistor SX is turned on, a potential of the second floating diffusion area FD2 or potentials of the first and second floating diffusion areas FD1 and FD2 electrically connected to each other may be amplified through the drive transistor DX and may be delivered to a drain of the selection transistor SX.

In some example embodiments of the present disclosure, in a low illumination mode, charges generated in the photo diode PD may move to the second floating diffusion area FD2 without loss or with reduced loss. To this end, a voltage level of the first floating diffusion area FD1 may be appropriately controlled by changing a voltage level of the gate electrode TG1 of the first transfer transistor TX1.

In more detail, the image sensor 100 may be exposed to generate charges in the photo diode PD. Afterward, when a high-level voltage may be provided to the gate electrode TG1 of the first transfer transistor TX1 to turn on the first transfer transistor TX1. In this case, because the gate electrode TG1 of the first transfer transistor TX1 is coupled to the first floating diffusion area FD1 by an overlap capacitor, the voltage level of the first floating diffusion area FD1 may also increase. Accordingly, because an asymmetric potential structure in which charges stored in the photo diode PD are capable of moving to the first floating diffusion area FD1 without loss or with reduced loss is formed, charges may move from the photo diode PD to the first floating diffusion area FD1 without loss or with reduced loss. For example, the charges may be stored in a storage diode SD of the first floating diffusion area FD1.

Afterward, when a low-level voltage may be provided to the gate electrode TG1 of the first transfer transistor TX1 to turn off the first transfer transistor TX1. In this case, because the gate electrode TG1 of the first transfer transistor TX1 is coupled to the first floating diffusion area FD1 by an overlap capacitor, the voltage level of the first floating diffusion area FD1 may also decrease. Accordingly, the voltage level of the first floating diffusion area FD1 may be lower than the voltage level of the second floating diffusion area FD2, and thus an asymmetric potential structure in which charges capable of moving from the first floating diffusion area FD1 to the second floating diffusion area FD2 without loss or with reduced loss may be formed. When the second transfer transistor TX2 is turned on, the charges stored in the storage diode SD of the first floating diffusion area FD1 move to a capacitor C of the second floating diffusion area FD2.

Afterward, the second transfer transistor TX2 may be turned off, and the voltage level of the second floating diffusion area FD2 may be sampled. Because a sampling operation is performed by using only the charges stored in a capacity of the capacitor C provided by the second floating diffusion area FD2, the relatively high conversion gain (HCG) may be provided.

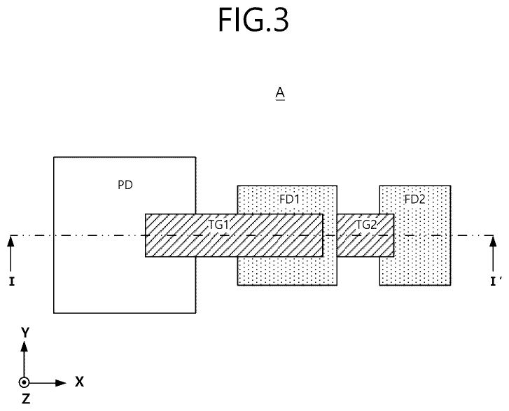

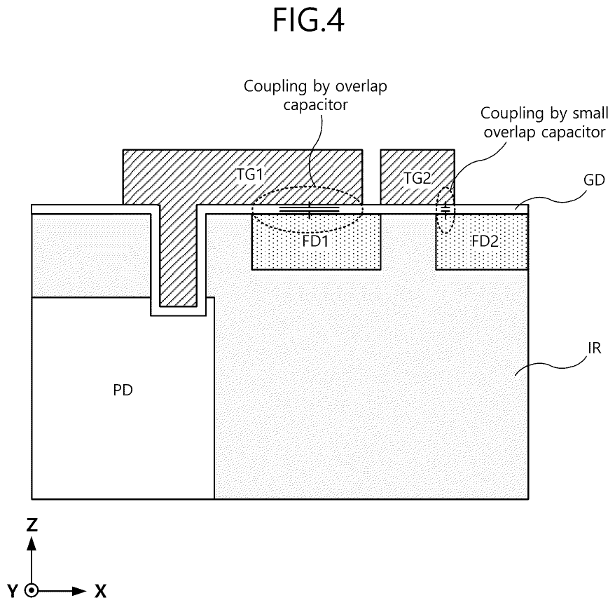

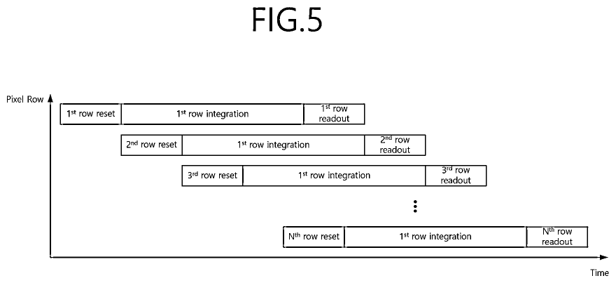

FIG. 3 is a plan view illustrating an example of an area ‘A’ of FIG. 2. FIG. 4 is a cross-sectional view illustrating the area ‘A’ of FIG. 3 taken along line I-I′. Referring to FIGS. 3 and 4, the gate electrode TG1 of the first transfer transistor TX1 may extend in a first direction (X direction), and a part of the gate electrode TG1 may be embedded in the photo diode PD in a third direction (Z direction). That is, the gate electrode TG1 may be a vertical transfer gate. The gate electrode TG2 of the second transfer transistor TX2 may extend in the first direction (X direction).

A gate insulating layer GD may be provided under the gate electrodes TG1 and TG2. For example, the gate insulating layer GD may include silicon oxide (SiOx), silicon oxynitride (SiOxNy), silicon nitride (SiNx), germanium oxynitride (GeOxNy), germanium silicon oxide (GeSixOy), or a material having a high dielectric constant. The material having a high dielectric constant may include at least one of hafnium oxide (HfOx), zirconium oxide (ZrOx), aluminum oxide (AlOx), tantalum oxide (TaOx), hafnium silicate (HfSix), or zirconium silicate (ZrSix).

The first floating diffusion area FD1 may partially overlap the gate electrode TG1 of the first transfer transistor TX1 when viewed in a horizontal direction. In particular, in some example embodiments of the present disclosure, the first floating diffusion area FD1 may widely overlap the gate electrode TG1, and thus a large-capacity overlap capacitor may be formed. Accordingly, the gate electrode TG1 of the first transfer transistor TX1 may be relatively strongly coupled to the first floating diffusion area FD1, and thus the voltage level of the first floating diffusion area FD1 may be controlled by changing the voltage level of the gate electrode TG1.

The second floating diffusion area FD2 may partially overlap the gate electrode TG2 of the second transfer transistor TX2 when viewed in a horizontal direction. For example, the second floating diffusion area FD2 may narrowly overlap the gate electrode TG2, and thus a small-capacity overlap capacitor may be formed. Accordingly, the gate electrode TG2 of the second transfer transistor TX2 may be relatively weakly coupled to the second floating diffusion area FD2. However, this is only an example. For example, the second floating diffusion area FD2 may not partially overlap the gate electrode TG2 of the second transfer transistor TX2 when viewed in the horizontal direction.

The first and second floating diffusion areas FD1 and FD2 may be areas doped with n+ by an ion implantation process.

An impurity area IR may be formed by implanting p-type impurities by using the ion implantation process. For example, the impurity area IR may be provided as a p-well area for the first and second transfer transistors TX1 and TX2.

As described above, the first floating diffusion area FD1 and the gate electrode TG1 of the first transfer transistor TX1 may overlap each other when viewed in the horizontal direction to form an overlap capacitor, and may be strongly coupled to each other through the overlap capacitor. Accordingly, the voltage level of the first floating diffusion area FD1 may be controlled by adjusting the voltage level of the gate electrode TG1, and thus an asymmetric potential structure for moving charges without loss or with reduced loss may be formed.

FIG. 5 is a diagram showing an operating method of the pixel array of FIG. 1.

Referring to FIG. 5, the pixel array 110 according to some example embodiments of the present disclosure may be driven by a rolling shutter scheme. For example, a row in which a reset operation or readout operation is performed may be different depending on a movement time. An image sensor according to some example embodiments of the present disclosure may provide excellent sensitivity when a static object or a slow-moving object is captured, by operating in the rolling shutter scheme.

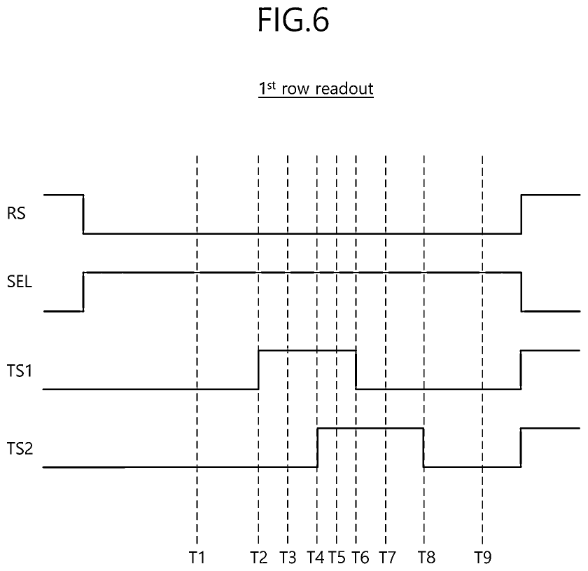

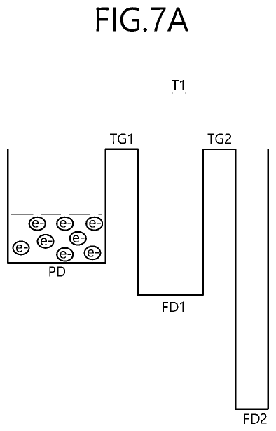

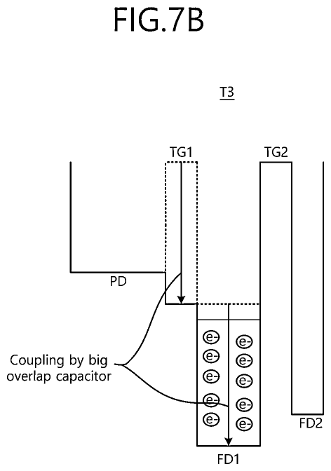

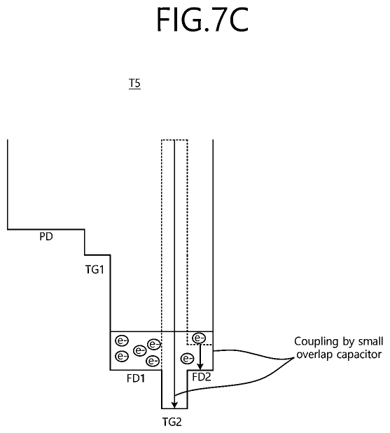

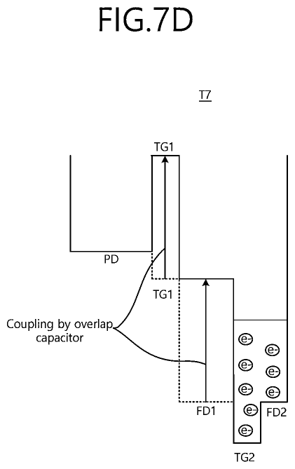

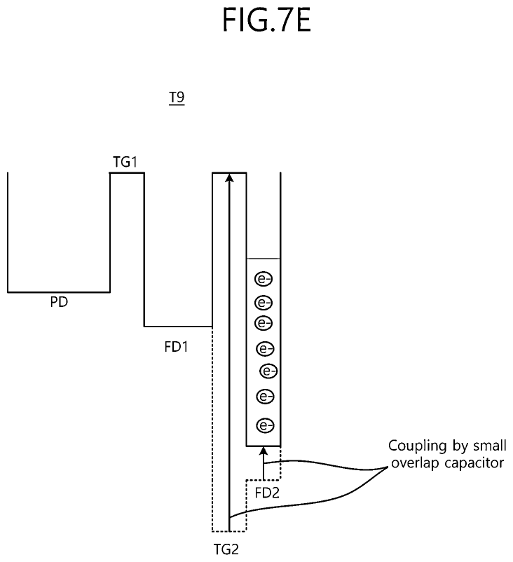

FIG. 6 is a timing diagram illustrating a readout operation of the unit pixel of FIG. 2. FIGS. 7A-E are diagrams illustrating a potential state of the unit pixel of FIG. 2.

Referring to FIG. 6, at time point T1, the reset signal RS and the first and second transmission signals TS1 and TS2 are at low levels. Accordingly, the reset transistor RX and the first and second transfer transistors TX1 and TX2 are turned off, and the first floating diffusion area FD1 and the second floating diffusion area FD2 are electrically blocked from each other to maintain a floating state. For example, as illustrated in FIG. 7A, the second floating diffusion area FD2 is blocked from the first floating diffusion area FD1 by a potential barrier of the gate electrode TG2 of the second transfer transistor TX2. The voltage level of the second floating diffusion area FD2 is sampled and is used as a reference voltage.

At time point T2, the first transmission signal TS1 transitions to a high level. Accordingly, the first transfer transistor TX1 is turned on, and charges accumulated in the photo diode PD move to the first floating diffusion area FD1. In this case, because the gate electrode TG1 of the first transfer transistor TX1 and the first floating diffusion area FD1 are strongly coupled by an overlap capacitor, the voltage level of the first floating diffusion area FD1 also increases. Accordingly, an asymmetric potential structure in which the charges are capable of moving from the photo diode PD to the first floating diffusion area FD1 without loss or with reduced loss is formed. Accordingly, as illustrated in FIG. 7B, at time point T3, all charges generated by the photo diode PD move to the first floating diffusion area FD1 without loss or with reduced loss.

At time point T4, the second transmission signal TS2 transitions to a high level. Accordingly, the second transfer transistor TX2 is turned on, and the second floating diffusion area FD2 and the first floating diffusion area FD1 are electrically connected with each other. Accordingly, the total capacity for storing charges increases to the sum of the capacity of the first floating diffusion area FD1 and the capacity of the second floating diffusion area FD2. In the meantime, because the gate electrode TG2 of the second transfer transistor TX2 is weakly coupled to the second floating diffusion area FD2, a change in a voltage level of the gate electrode TG2 does not significantly affect a voltage level of the second floating diffusion area FD2. Accordingly, as illustrated in FIG. 7C, at time point T5, charges stored in the first floating diffusion area FD1 are shared by the first and second floating diffusion areas FD1 and FD2.

At time point T6, the first transmission signal TS1 transitions to a low level. Accordingly, the first transfer transistor TX1 is turned off. In this case, because the gate electrode TG1 of the first transfer transistor TX1 and the first floating diffusion area FD1 are strongly coupled to each other, the voltage level of the first floating diffusion area FD1 also decreases. Accordingly, the charges stored in the first floating diffusion area FD1 do not move in a direction of the photo diode PD, but move in a direction of the second floating diffusion area FD2. Accordingly, as illustrated in FIG. 7D, at time point T7, all the charges stored in the first floating diffusion area FD1 move to a channel of the second transfer transistor TX2 and the second floating diffusion area FD2 without loss or with reduced loss.

At time point T8, the second transmission signal TS2 transitions to a low level. Accordingly, the second transfer transistor TX2 is turned off. In this case, because the gate electrode TG2 of the second transfer transistor TX2 is weakly coupled to the second floating diffusion area FD2, a change in a voltage level of the gate electrode TG2 does not significantly affect the voltage level of the second floating diffusion area FD2. Accordingly, the asymmetric potential structure in which the voltage level of the second floating diffusion area FD2 is higher than the voltage level of the first floating diffusion area FD1 is maintained, and thus charges positioned in the channel of the second transfer transistor TX2 do not move in a direction of the first floating diffusion area FD1, but move in a direction of the second floating diffusion area FD2. Accordingly, as shown in FIG. 7E, at time point T9, all charges positioned in the channel of the second transfer transistor TX2 also move to the second floating diffusion area FD2 without loss or with reduced loss.

At time point T9, the voltage level of the second floating diffusion area FD2 is sampled. The voltage level of the second floating diffusion area FD2 may be defined as a signal voltage. A digital code may be output by comparing a first signal voltage with the reference voltage sampled at time point T1. As such, as all the charges generated by the photo diode PD move to the second floating diffusion area FD2 without loss or with reduced loss, a high-sensitivity sampling operation may be performed to provide the high conversion gain (HCG).

In the meantime, a readout operation of the unit pixel 112 of FIG. 2 may be variously modified to provide the high conversion gain (HCG). In particular, an asymmetric potential structure for obtaining the high conversion gain (HCG) may be formed through an operating method of turning off the first transfer transistor TX1 before the second transfer transistor TX2. Hereinafter, operating methods of the unit pixel 112 according to some other example embodiments of the present disclosure for obtaining the high conversion gain (HCG) will be described in more detail.

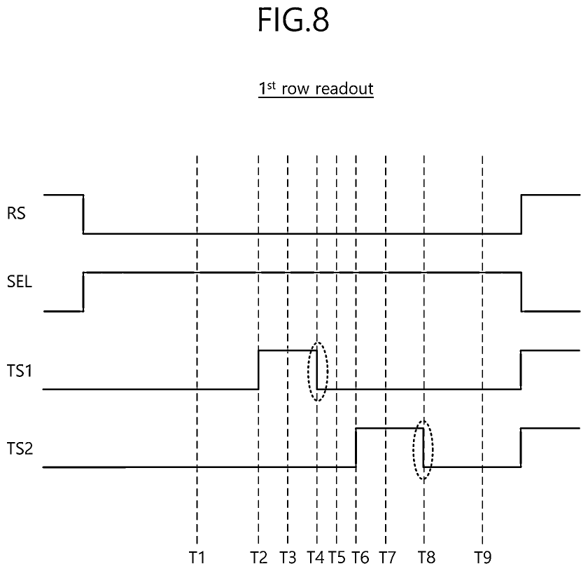

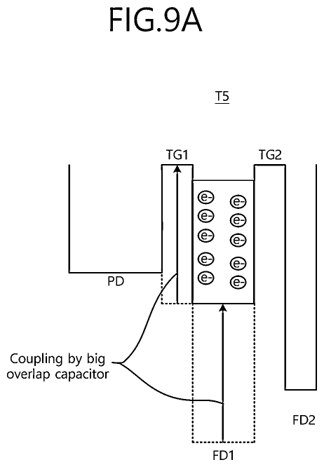

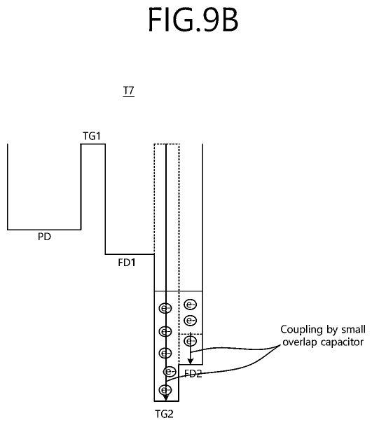

FIG. 8 is a timing diagram illustrating another example of a readout operation of the unit pixel of FIG. 2. FIGS. 9A-B are diagrams illustrating a potential state of a unit pixel according to the readout operation of FIG. 8. A readout operation of FIGS. 8 and 9 and a potential state of a unit pixel according to the readout operation are similar to or the same as those of FIGS. 6 and 7. Accordingly, redundant descriptions will be omitted below.

Referring to FIG. 8, at time point T1, the reset transistor RX and the first and second transfer transistors TX1 and TX2 are turned off, and the first floating diffusion area FD1 and the second floating diffusion area FD2 are electrically blocked from each other to maintain a floating state. The voltage level of the second floating diffusion area FD2 is sampled and is used as a reference voltage in a low illumination mode.

At time point T2, the first transmission signal TS1 transitions to a high level. Accordingly, an asymmetric potential structure in which the charges are capable of moving from the photo diode PD to the first floating diffusion area FD1 without loss or with reduced loss is formed.

At time point T3, all the charges generated by the photo diode PD move to the first floating diffusion area FD1 without loss or with reduced loss.

At time point T4, the first transmission signal TS1 transitions to a low level. Accordingly, the first transfer transistor TX1 is turned off. In this case, because the gate electrode TG1 of the first transfer transistor TX1 and the first floating diffusion area FD1 are strongly coupled to each other, the voltage level of the first floating diffusion area FD1 also decreases. Because the second transfer transistor TX2 is turned off, as shown in FIG. 9A, at time point T5, the charges stored in the first floating diffusion area FD1 are maintained without loss or with reduced loss in the first floating diffusion area FD1 by channel barriers of the gate electrodes TG1 and TG2.

At time point T6, the second transmission signal TS2 transitions to a high level. Accordingly, the second transfer transistor TX2 is turned on. Because the gate electrode TG2 of the second transfer transistor TX2 is weakly coupled to the second floating diffusion area FD2, the voltage level of the second floating diffusion area FD2 also increases slightly as the voltage level of the gate electrode TG2 increases. In this case, the voltage level of the first floating diffusion area FD1 may be lower than the voltage level of the second floating diffusion area FD2, and thus the asymmetric potential structure in which charges stored in the first floating diffusion area FD1 are capable of moving to the second floating diffusion area FD2 may be formed. Accordingly, as illustrated in FIG. 9B, at time point T7, the charges stored in the first floating diffusion area FD1 move to the second transfer transistor TX2 and the second floating diffusion area FD2 without loss or with reduced loss.

At time point T8, the second transmission signal TS2 transitions to a low level, and the second transfer transistor TX2 is turned off. In this case, because the gate electrode TG2 of the second transfer transistor TX2 is weakly coupled to the second floating diffusion area FD2, an asymmetric potential structure in which the voltage level of the second floating diffusion area FD2 is higher than the voltage level of the first floating diffusion area FD1 is maintained, and thus charges positioned in the channel of the second transfer transistor TX2 do not move in a direction of the first floating diffusion area FD1, but move in a direction of the second floating diffusion area FD2.

At time point T9, the voltage level of the second floating diffusion area FD2 is sampled. The voltage level of the second floating diffusion area FD2 may be defined as a signal voltage, and a digital code may be output by comparing a first signal voltage with the reference voltage sampled at time point T1.

As described above, a readout operation of the unit pixel for providing the high conversion gain (HCG) may also be performed in a manner, in which the first transfer transistor TX1 is first turned on and turned off, and then the second transfer transistor TX2 is turned on and turned off.

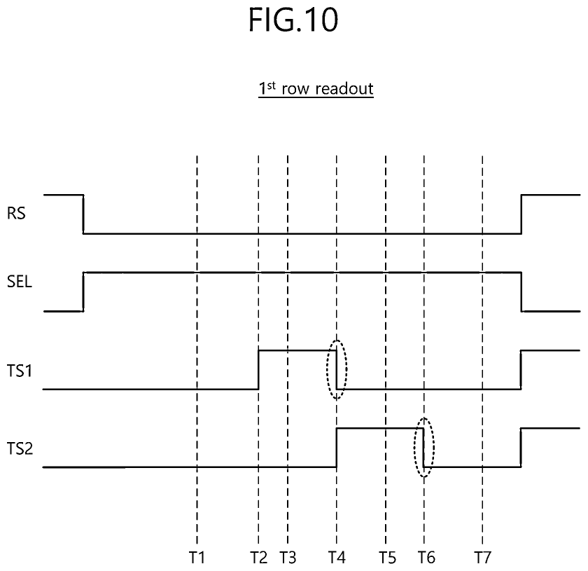

FIG. 10 is a timing diagram illustrating another example of a readout operation of the unit pixel of FIG. 2. A readout operation of FIG. 10 is similar to or the same as that of FIG. 8. Accordingly, redundant descriptions will be omitted below.

The readout operation of FIG. 10 is the same as the readout operation of FIG. 8 except that, at time point T4, the first transmission signal TS1 transitions to a low level and the second transmission signal TS2 transitions to a high-level at the same time.

In other words, the readout operation of FIG. 8 is performed in the order of turning on the first transfer transistor TX1, turning off the first transfer transistor TX1, turning on the second transfer transistor TX2, and turning off the second transfer transistor TX2. On the other hand, the readout operation of FIG. 10 is performed in the order of turning on the first transfer transistor TX1, an operation of turning off the first transfer transistor TX1 and simultaneously or contemporaneously turning on the second transfer transistor TX2, and turning off the second transfer transistor TX2.

In detail, referring to FIG. 10, at time point T4, the first transfer transistor TX1 is turned off and the second transfer transistor TX2 is turned on at the same time. In this case, as the first transmission signal TS1 transitions to a low level, a voltage level of the first floating diffusion area FD1 decreases. As the second transmission signal TS2 transitions to a high level, a voltage level of the second floating diffusion area FD2 decreases to a specific extent. Accordingly, as described with reference to FIG. 8, the charges stored in the first floating diffusion area FD1 move to the second transfer transistor TX2 and the second floating diffusion area FD2 without loss or with reduced loss.

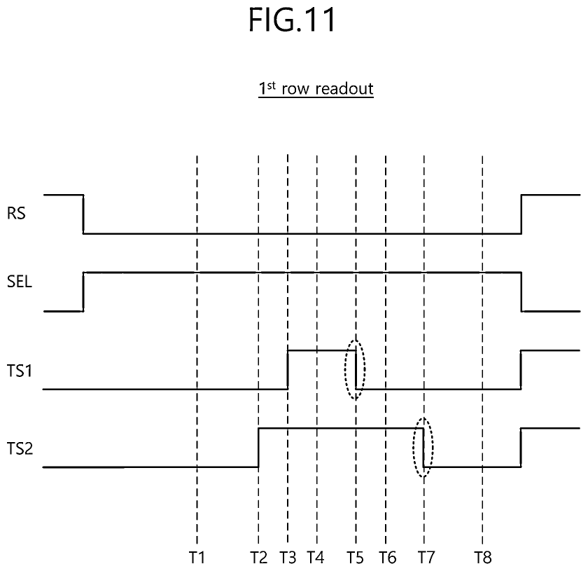

FIG. 11 is a timing diagram illustrating another example of a readout operation of the unit pixel of FIG. 2. A readout operation of FIG. 11 is similar to or the same as that of FIGS. 6, 8, and 10. Accordingly, redundant descriptions will be omitted below.

Referring to FIG. 11, at time point T1, the first floating diffusion area FD1 and the second floating diffusion area FD2 are electrically blocked from each other to maintain a floating state. The voltage level of the second floating diffusion area FD2 is sampled and is used as a reference voltage in a low illumination mode.

At time point T2, the second transmission signal TS2 transitions to a high level. Accordingly, the second transfer transistor TX2 is turned on, and the first floating diffusion area FD1 and the second floating diffusion area FD2 are electrically connected with each other. Accordingly, the total capacity for storing charges is provided to the sum (SD+C) of the capacity of the first floating diffusion area FD1 and the capacity of the second floating diffusion area FD2.

At time point T3, the first transmission signal TS1 transitions to a high level. Because the gate electrode TG1 of the first transfer transistor TX1 and the first floating diffusion area FD1 are strongly coupled to each other, voltage levels of the first and second floating diffusion areas FD1 and FD2 thus electrically connected also increase. Accordingly, an asymmetric potential structure in which the charges are capable of moving from the photo diode PD to the first floating diffusion area FD1 without loss or with reduced loss is formed.

At time point T4, all the charges generated by the photo diode PD move to the first floating diffusion area FD1 without loss or with reduced loss.

At time point T5, the first transmission signal TS1 transitions to a low level. Accordingly, the first transfer transistor TX1 is turned off. In this case, because the gate electrode TG1 of the first transfer transistor TX1 and the first floating diffusion area FD1 are strongly coupled to each other, the voltage level of the first floating diffusion area FD1 also decreases. In the meantime, because the second transfer transistor TX2 is turned on, the voltage level of the second floating diffusion area FD2 remains in a relatively high state. Accordingly, a potential structure in which charges stored in the first floating diffusion area FD1 move to the second transfer transistor TX2 and the second floating diffusion area FD2 without loss or with reduced loss is formed.

Accordingly, at time point T6, the charges stored in the first floating diffusion area FD1 move to the second transfer transistor TX2 and the second floating diffusion area FD2 without loss or with reduced loss.

At time point T7, the second transmission signal TS2 transitions to a low level. Accordingly, the second transfer transistor TX2 is turned off. In this case, because the gate electrode TG2 of the second transfer transistor TX2 is weakly coupled to the second floating diffusion area FD2, a change in a voltage level of the gate electrode TG2 does not significantly affect the voltage level of the second floating diffusion area FD2. Accordingly, the asymmetric potential structure in which the voltage level of the second floating diffusion area FD2 is higher than the voltage level of the first floating diffusion area FD1 is maintained, and thus charges positioned in the channel of the second transfer transistor TX2 do not move in a direction of the first floating diffusion area FD1, but move in a direction of the second floating diffusion area FD2.

At time point T8, all charges positioned in the channel of the second transfer transistor TX2 move to the second floating diffusion area FD2 without loss or with reduced loss, and the voltage level of the second floating diffusion area FD2 is sampled.

As described above, when viewed in the horizontal direction, the gate electrode TG1 of the first transfer transistor TX1 and the first floating diffusion area FD1 of the unit pixel 112 according to some example embodiments of the present disclosure may overlap each other and may be strongly coupled to each other. Accordingly, the asymmetric potential structure for moving charges without loss or with reduced loss may be easily formed by controlling the voltage level of the first floating diffusion area FD1 through the adjustment of the voltage level of the gate electrode TG1. In particular, as described with reference to FIGS. 6 to 11, the asymmetric potential structure for obtaining the high conversion gain (HCG) may be easily formed through an operating method of turning off the first transfer transistor TX1 before the second transfer transistor TX2.

[Image sensor supporting Low Conversion Gain]

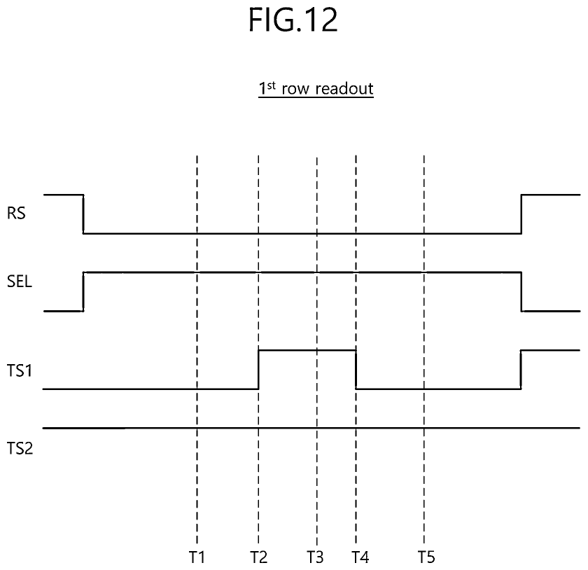

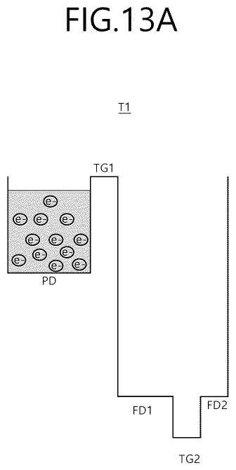

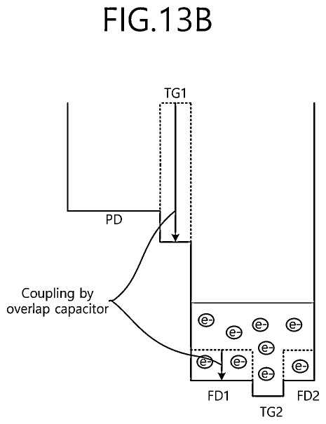

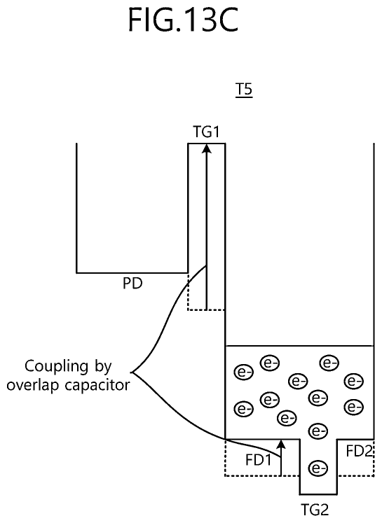

FIG. 12 is a timing diagram illustrating a readout operation of the unit pixel of FIG. 2. FIGS. 13A-C are diagrams illustrating a potential state of the unit pixel of FIG. 2. In FIGS. 12 and 13A-C, the unit pixel 112 of FIG. 2 may be implemented to provide a low conversion gain (LCG) in a high illumination mode.

For example, in a high illumination mode, charges exceeding the maximum capacity capable of being stored in the photo diode PD are generated, and thus over-flow charges may climb over a channel potential barrier of the transfer transistor TX. Alternatively, in a high illumination mode, charges exceeding the capacity capable of being stored in the second floating diffusion area FD2 are generated, and thus the remaining charges may be discarded.

In the unit pixel 112 according to some example embodiments of the present disclosure, the second transfer transistor TX2 may continuously maintain a turn-on state during a readout operation. In this case, the total capacity capable of storing charges may be extended to the sum (i.e., SD+C) of capacities of the first floating diffusion area FD1 and the second floating diffusion area FD2, and overflowed or remaining charges may be used to perform a sampling operation without being discarded.

In more detail with reference to FIGS. 12 and 13, at time point T1, the second transmission signal TS2 is at a high level. Accordingly, the second transfer transistor TX2 is turned on, and the first floating diffusion area FD1 and the second floating diffusion area FD2 are electrically connected to each other. Moreover, the reset signal RS and the first transmission signal TS1 are at low levels, and thus the electrically connected first and second floating diffusion areas FD1 and FD2 are in floating states as shown in FIG. 13A. The voltage level of the first and second floating diffusion areas FD1 and FD2 thus electrically connected to each other is sampled and used as a reference voltage.

At time point T2, the first transmission signal TS1 transitions to a high level. Accordingly, the first transfer transistor TX1 is turned on, and charges accumulated in the photo diode PD move to the first and second floating diffusion areas FD1 and FD2. In this case, because the gate electrode TG1 of the first transfer transistor TX1 and the first floating diffusion area FD1 are strongly coupled by an overlap capacitor, the voltage levels of the first and second floating diffusion areas FD1 and FD2 also increase. Accordingly, an asymmetric potential structure in which the charges are capable of moving from the photo diode PD to the first and second floating diffusion areas FD1 and FD2 without loss or with reduced loss may be formed. Accordingly, as illustrated in FIG. 13B, at time point T3, all charges generated by the photo diode PD move to the first and second floating diffusion areas FD1 and FD2 without loss or with reduced loss. In particular, because the total capacity capable of storing charges increases to the sum of capacities of the first and second floating diffusion areas FD1 and FD2, overflowed charges may be stored without being discarded.

At time point T4, the first transmission signal TS1 transitions to a low level, and the first transfer transistor TX1 is turned off. In this case, the voltage levels of the first and second floating diffusion areas FD1 and FD2 are also lowered, but the gate electrode TG1 of the first transfer transistor TX1 is lowered faster. That is, a potential barrier by the gate electrode TG1 is formed faster. Accordingly, as shown in FIG. 13C, at time point T5, the charges remain stable without leakage in the first and second floating diffusion areas FD1 and FD2. Afterward, the voltage level of the first and second floating diffusion areas FD1 and FD2 thus electrically connected to each other is sampled, which may be defined as signal voltages. A digital code may be output by comparing a first signal voltage with the reference voltage sampled at time point T1.

As such, in the high illumination mode, the total capacity for storing charges may be extended to the sum of capacities of the first floating diffusion area FD1 and the second floating diffusion area FD2. Accordingly, overflowed or remaining charges may be used to perform a sampling operation without being discarded, thereby providing an accurate low conversion gain (LCG).

[Image Sensor providing Dual Conversion Gain Mode]

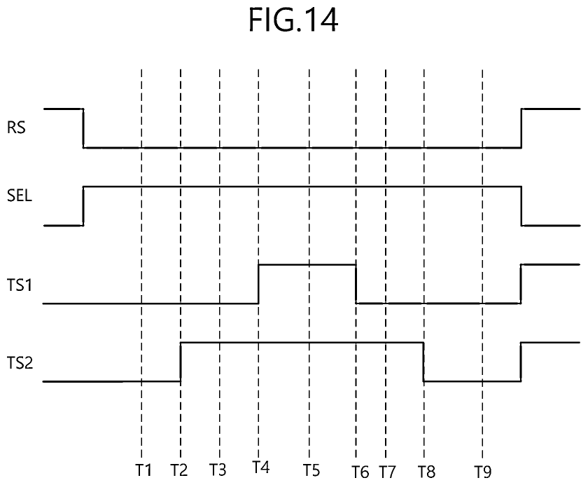

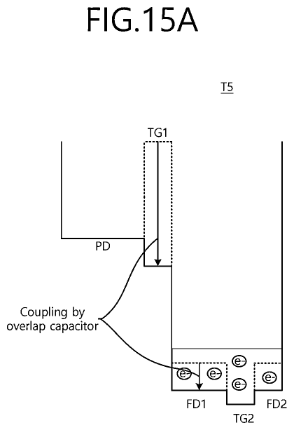

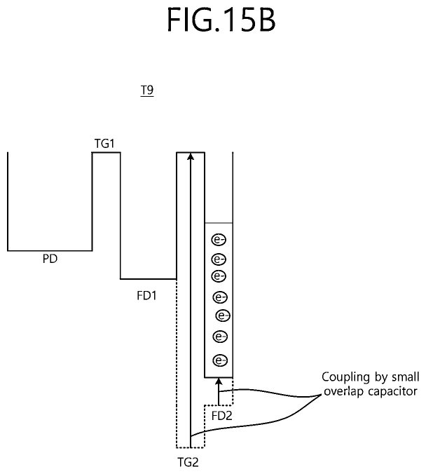

FIG. 14 is a timing diagram illustrating a readout operation of the unit pixel of FIG. 2. FIGS. 15A-B is a diagram illustrating a potential state of the unit pixel of FIG. 2. In FIGS. 14 and 15A-B, the unit pixel 112 of FIG. 2 may support a dual conversion gain mode providing both a high conversion gain (HCG) and a low conversion gain (LCG).

For example, in a low illumination mode, the unit pixel 112 according to some example embodiments of the present disclosure may form an asymmetric potential structure through coupling between the gate electrode TG1 of the first transfer transistor TX1 and the first floating diffusion area FD1, and thus charges generated by the photo diode PD may move to the second floating diffusion area FD2 without loss or with reduced loss. Moreover, in a high illumination mode, the unit pixel 112 may extend the total capacity capable of storing charges to the sum of capacities of the first floating diffusion area FD1 and the second floating diffusion area FD2, and thus may use overflowed or remaining charges to perform a sampling operation while the charges are not discarded.

In more detail with reference to FIGS. 14 and 15, at time point T1, the reset signal RS and the first and second transmission signals TS1 and TS2 are at low levels. Accordingly, the reset transistor RX and the first and second transfer transistors TX1 and TX2 are turned off, and the first floating diffusion area FD1 and the second floating diffusion area FD2 are electrically blocked from each other to maintain a floating state. The voltage level of the second floating diffusion area FD2 is sampled and used as the first reference voltage (1^{St} reference voltage) for the high conversion gain (HCG).

At time point T2, the second transmission signal TS2 transitions to a high level. Accordingly, the first floating diffusion area FD1 and the second floating diffusion area FD2 are electrically connected with each other.

At time point T3, the voltage level of the first and second floating diffusion areas FD1 and FD2 thus electrically connected is sampled. The sampled voltage level of the first and second floating diffusion areas FD1 and FD2 is used as a second reference voltage (2′ reference voltage) for the low conversion gain (LCG).

At time point T4, the first transmission signal TS1 transitions to a high level. Accordingly, the first transfer transistor TX1 is turned on, and charges accumulated in the photo diode PD move to the first and second floating diffusion areas FD1 and FD2.

At time point T5, the voltage level of the first and second floating diffusion areas FD1 and FD2 thus electrically connected to each other is sampled, which may be defined as a second signal voltage (2n d signal voltage). For example, as shown in FIG. 15A, the total capacity is expanded to the sum (SD+C) of the capacities of the first and second floating diffusion areas FD1 and FD2, and thus a large amount of charges may be stored. A digital code may be output by comparing the second signal voltage with the second reference voltage sampled at time point T3. As such, the low conversion gain (LCG) may be provided by using both the capacities of the first and second floating diffusion areas FD1 and FD2.

At time point T6, the first transmission signal TS1 transitions to a low level. Accordingly, the first transfer transistor TX1 is turned off. In this case, because the gate electrode TG1 of the first transfer transistor TX1 and the first floating diffusion area FD1 are strongly coupled to each other, the voltage level of the first floating diffusion area FD1 also decreases. Accordingly, charges stored in the first floating diffusion area FD1 do not move in a direction of the photo diode PD, but move in a direction of the second transfer transistor TX2 and the second floating diffusion area FD2.

Accordingly, at time point T7, all the charges stored in the first floating diffusion area FD1 are stored in the second transfer transistor TX2 and the second floating diffusion area FD2 without loss or with reduced loss.

At time point T8, the second transmission signal TS2 transitions to a low level. Accordingly, the second transfer transistor TX2 is turned off. In this case, because the gate electrode TG2 of the second transfer transistor TX2 is weakly coupled to the second floating diffusion area FD2, a change in a voltage level of the gate electrode TG2 does not significantly affect the voltage level of the second floating diffusion area FD2. Accordingly, an asymmetric potential structure in which the voltage level of the second floating diffusion area FD2 is higher than the voltage level of the first floating diffusion area FD1 is maintained, and thus charges positioned in the channel of the second transfer transistor TX2 do not move in the direction of the first floating diffusion area FD1, but move in the direction of the second floating diffusion area FD2. Accordingly, as shown in FIG. 15B, at time point T9, all charges positioned in the channel of the second transfer transistor TX2 also move to the second floating diffusion area FD2 without loss or with reduced loss.

At time point T9, the voltage level of the second floating diffusion area FD2 is sampled. The voltage level of the second floating diffusion area FD2 may be defined as a first signal voltage (1^{st} signal voltage). A digital code may be output by comparing the first signal voltage with the first reference voltage sampled at time point T1. As such, the high conversion gain (HCG) may be provided by using only the capacity ‘C’ of the second floating diffusion area FD2, thereby performing a high-sensitivity sampling operation.

As described above, the unit pixel 112 according to some example embodiments of the present disclosure may provide a dual conversion gain (DCG) mode that provides both the high conversion gain (HCG) and the low conversion gain (LCG). In addition, the high-sensitivity sampling operation may be performed without loss or with reduced loss of charge by forming the asymmetric potential structure through an overlap capacitor due to the overlap of the first transfer transistor TX1 and the first floating diffusion area FD1.

On the other hand, a structure of the unit pixel according to some example embodiments of the present disclosure may be variously modified. Hereinafter, various modifications will be described in detail.

### Various Modified Examples of Gate Electrode

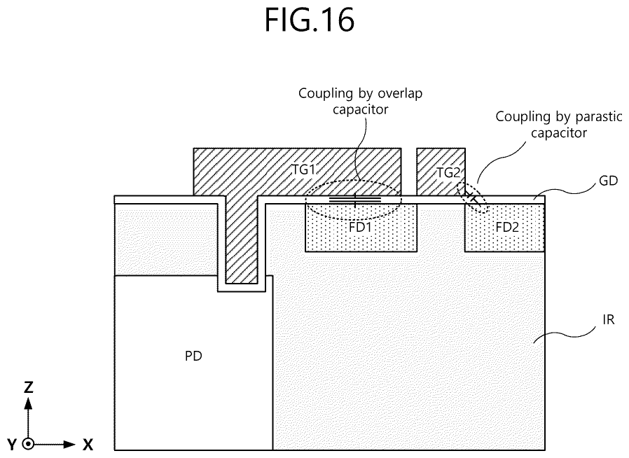

FIGS. 16 to 18 are cross-sectional views illustrating various examples of area ‘A’ of FIG. 2. Illustrations of FIGS. 16 to 18 are similar to or the same as the illustration of FIG. 4. Accordingly, redundant descriptions will be omitted below.

Referring to FIG. 16, the gate electrode TG2 of the second transfer transistor TX2 extends in a first direction (X direction) and does not partially overlap the second floating diffusion area FD2 when viewed in a horizontal direction. That is, the gate electrode TG2 of the second transfer transistor TX2 of FIG. 4 partially overlaps the second floating diffusion area FD2 when viewed in the horizontal direction. On the other hand, the gate electrode TG2 of FIG. 16 does not overlap the second floating diffusion area FD2.

In this case, a parasitic capacitor may be present between the gate electrode TG2 and the second floating diffusion area FD2, and thus the gate electrode TG2 may be weakly coupled to the second floating diffusion area FD2. As a result, even though a structure of FIG. 16 is adopted, a unit pixel according to some example embodiments of the present disclosure may be driven to provide the high conversion gain (HCG), the low conversion gain (LCG), or the dual conversion gain (DCG) described with reference to FIGS. 5 to 15.

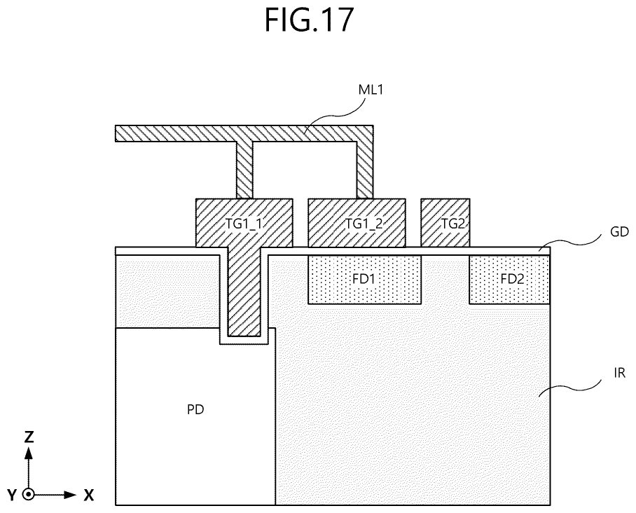

Referring to FIG. 17, the first gate electrode TG1 may be physically divided into a first sub-gate electrode TG1_1 and a second sub-gate electrode TG1_2. In this case, the first transmission signal TS1 may be simultaneously or contemporaneously provided to the first sub-gate electrode TG1_1 and the second sub-gate electrode TG1_2 through a first metal line ML1. As a result, even though a structure of FIG. 17 is adopted, a unit pixel according to some example embodiments of the present disclosure may be driven to provide the high conversion gain (HCG), the low conversion gain (LCG), or the dual conversion gain (DCG) described with reference to FIGS. 5 to 15.

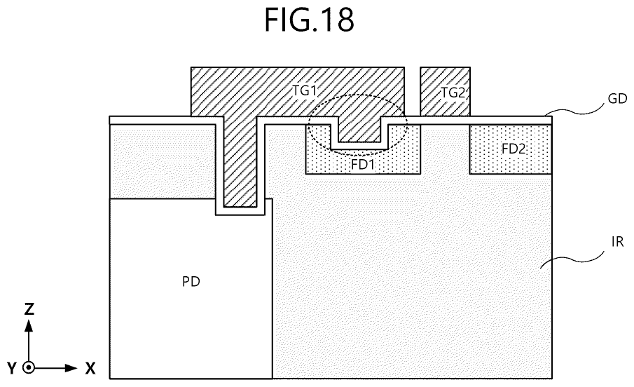

Referring to FIG. 18, the gate electrode TG1 of the first transfer transistor TX1 overlaps the first floating diffusion area FD1 when viewed in a horizontal direction and may have a concave-convex structure in the overlapping area. Accordingly, an overlap capacitor having a larger capacity may be formed between the gate electrode TG1 and the first floating diffusion area FD1, and the gate electrode TG1 and the first floating diffusion area FD1 may be strongly coupled to each other. As a result, an asymmetric potential structure in which the charges are capable of moving from the photo diode PD to the second floating diffusion area FD2 without loss or with reduced loss may be formed easily.

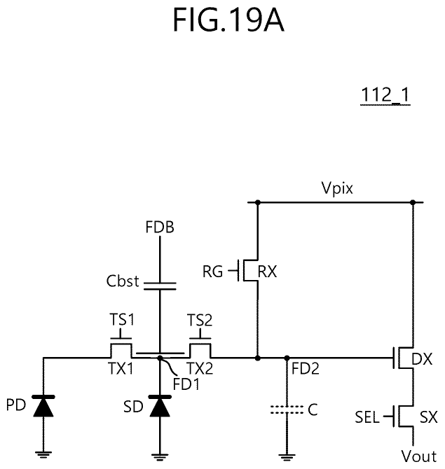

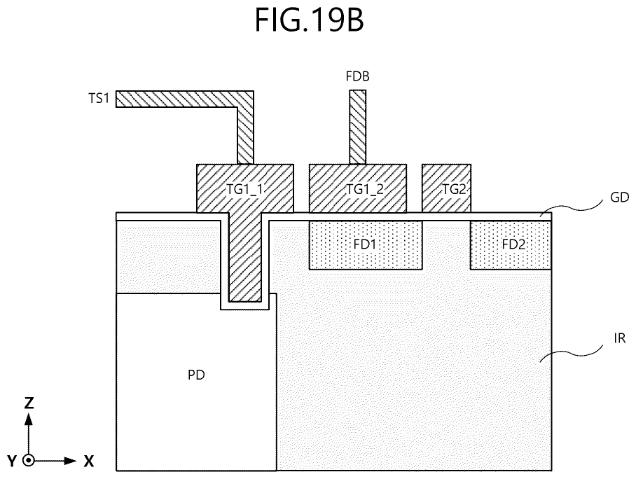

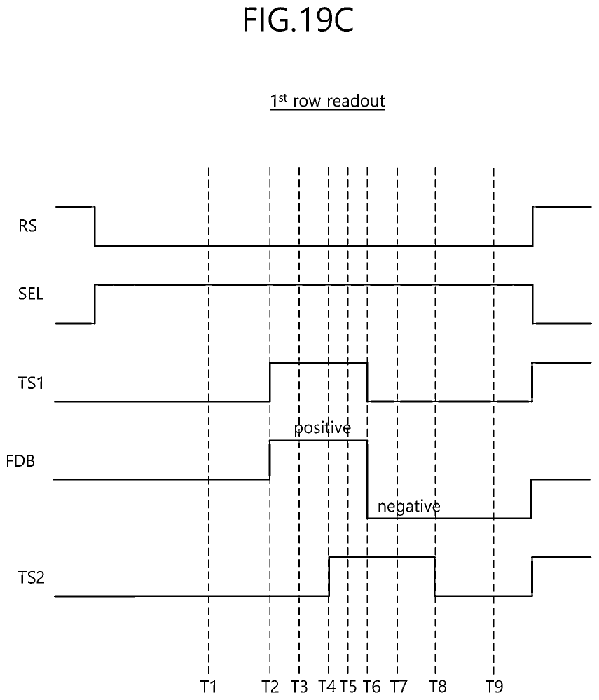

FIGS. 19A-C are diagrams for describing a unit pixel 112_1, according to some other example embodiments of the present disclosure. In detail, FIG. 19A is a circuit diagram of the unit pixel 112_1, according to some other example embodiments of the present disclosure; FIG. 19B is a cross-sectional view of an area ‘A’ of the unit pixel 112_1; and, FIG. 19C is a timing diagram for describing an operation of the unit pixel 112_1. The configuration and operation of the unit pixel of FIGS. 19A to 19C are similar to or the same as the configuration and operation of the unit pixel of FIGS. 2 to 7. Accordingly, redundant descriptions will be omitted below.

Referring to FIG. 19A, the unit pixel 112_1 may include the one photo diode PD, the five NMOS transistors TX1, TX2, RX, DX, and SX, and one boosting capacitor Cbst.

The boosting capacitor Cbst may be connected to the first floating diffusion area FD1. The boosting capacitor Cbst may be coupled to the first floating diffusion area FD1 to increase or decrease a voltage level of the first floating diffusion area FD1. For example, when a positive voltage is provided as a boosting signal FDB, a voltage level of the first floating diffusion area FD1 may increase. As another example, when a negative voltage is provided as the boosting signal FDB, the voltage level of the first floating diffusion area FD1 may decrease. Accordingly, an asymmetric potential structure may be formed strongly such that charges generated by the photo diode PD are capable of moving to the second floating diffusion area FD2 without loss or with reduced loss.

The boosting capacitor Cbst may be formed in various manners. For example, as shown in FIG. 19B, boosting metal may be provided to form the boosting capacitor Cbst. The boosting metal may be disposed parallel to metal (hereinafter, referred to as “first FD metal”) constituting the first floating diffusion area FD1 in a second direction (Y direction). Accordingly, the boosting capacitor Cbst may be formed between the boosting metal and the first FD metal. As another example, the boosting capacitor Cbst may be implemented by forming a metal on an insulator disposed on the top surface of the first floating diffusion area FD1. In general, the insulator is applied on the floating diffusion area. Accordingly, when a metal is formed on the insulator disposed on the top surface of the floating diffusion area, the metal constitutes one electrode of the boosting capacitor. Accordingly, the boosting capacitor Cbst may be formed by forming the boosting metal on the insulator disposed on the top surface of the first floating diffusion area FD1. In this case, a value of the boosting capacitor Cbst may be controlled by adjusting the thickness or material of the insulator in an area where the boosting capacitor is defined.

When an operation of the unit pixel 112_1 in the low illumination mode is described with reference to FIG. 19C, at time point T1, the reset signal RS and the first and second transmission signals TS1 and TS2 are at low levels. Accordingly, the reset transistor RX and the first and second transfer transistors TX1 and TX2 are turned off, and the first floating diffusion area FD1 and the second floating diffusion area FD2 are electrically blocked from each other to maintain a floating state. The voltage level of the second floating diffusion area FD2 is sampled and is used as a reference voltage.

At time point T2, the first transmission signal TS1 transitions to a high level, and a positive voltage is provided as the boosting signal FDB. Because the gate electrode TG1 of the first transfer transistor TX1 and the first floating diffusion area FD1 are strongly coupled by an overlap capacitor, the voltage level of the first floating diffusion area FD1 also increases. Furthermore, because the positive voltage is provided as the boosting signal FDB, the voltage level of the first floating diffusion area FD1 is further increased. Accordingly, the asymmetric potential structure in which charges are capable of moving from the photo diode PD to the first floating diffusion area FD1 without loss or with reduced loss may be formed strongly.

At time point T3, all the charges generated by the photo diode PD move to the first floating diffusion area FD1 without loss or with reduced loss.

At time point T4, the second transmission signal TS2 transitions to a high level. Accordingly, the second transfer transistor TX2 is turned on, and the second floating diffusion area FD2 and the first floating diffusion area FD1 are electrically connected with each other. Accordingly, the total capacity for storing charges increases to the sum of the capacity of the first floating diffusion area FD1 and the capacity of the second floating diffusion area FD2.

At time point T5, the charges stored in the first floating diffusion area FD1 are shared by the first and second floating diffusion areas FD1 and FD2.

At time point T6, the first transmission signal TS1 transitions to a low level, and a negative voltage is provided as the boosting signal FDB. Because the gate electrode TG1 of the first transfer transistor TX1 and the first floating diffusion area FD1 are strongly coupled to each other, the voltage level of the first floating diffusion area FD1 also decreases. Furthermore, because the negative voltage is provided as the boosting signal FDB, the voltage level of the first floating diffusion area FD1 is further decreased. Accordingly, the charges stored in the first floating diffusion area FD1 do not move in a direction of the photo diode PD, but move in a direction of the second floating diffusion area FD2 easily.

Accordingly, at time point T7, all the charges stored in the first floating diffusion area FD1 move to the second transfer transistor TX2 and the second floating diffusion area FD2 without loss or with reduced loss.

At time point T8, the second transmission signal TS2 transitions to a low level. Accordingly, the second transfer transistor TX2 is turned off. Because the asymmetric potential structure in which the voltage level of the second floating diffusion area FD2 is higher than the voltage level of the first floating diffusion area FD1 is maintained, charges positioned in the channel of the second transfer transistor TX2 do not move in the direction of the first floating diffusion area FD1, but move in the direction of the second floating diffusion area FD2.

At time point T9, all charges positioned in the channel of the second transfer transistor TX2 also move to the second floating diffusion area FD2 without loss or with reduced loss. Afterward, the voltage level of the second floating diffusion area FD2 is sampled. The voltage level of the second floating diffusion area FD2 may be defined as a signal voltage. A digital code may be output by comparing a signal voltage with the reference voltage sampled at time point T1.

As such, all charges generated by the photo diode PD safely move to the second floating diffusion area FD2, by controlling the voltage level of the first floating diffusion area FD1 through a boosting capacitor. Accordingly, a high-sensitivity sampling operation of providing the high conversion gain (HCG) may be performed.

[Image Sensor Including Three or More Floating Diffusion Areas]

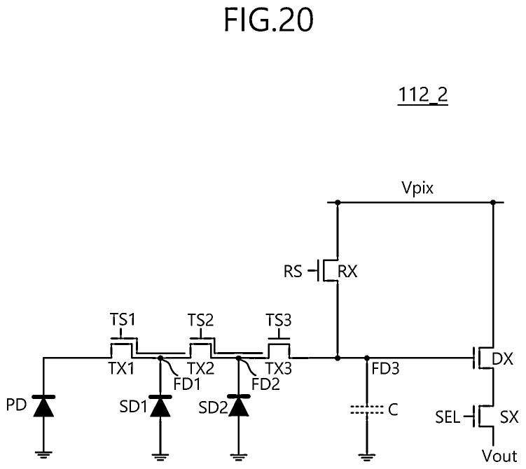

FIG. 20 is a circuit diagram illustrating a unit pixel 112_2, according to some other example embodiments of the present disclosure. A structure of the unit pixel 112_2 of FIG. 20 is similar to or the same as that of the unit pixel 112 of FIG. 2. Accordingly, the same or similar components are described by using the same or similar reference numerals, and redundant descriptions will be omitted below.

In FIG. 2, the unit pixel 112 is illustrated and described as including the two floating diffusion areas FD1 and FD2. However, this is an example, and the technical idea of the present disclosure is not limited thereto. For example, as illustrated in FIG. 20, the unit pixel 112_2 may further include a third floating diffusion area FD3. In addition, a third transfer transistor TX3 for connecting the third floating diffusion area FD3 to the second floating diffusion area FD2 may be further provided. In this case, to form an asymmetric potential structure in which charges generated by the photo diode PD are capable of moving to the third floating diffusion area FD3, the gate electrode TG2 of the second transfer transistor TX2 may overlap the second floating diffusion area FD2 when viewed in the horizontal direction. As such, the unit pixel 112_2 of FIG. 20 may provide a wide dynamic range by providing an additional floating diffusion area and an additional transfer transistor.

In some example embodiments, in a first mode, the first transfer transistor TX1 may be turned on while both the second and third transfer transistors TX2 and TX3 are turned on. In this case, while the first to third floating diffusion areas FD1 to FD3 are electrically connected to each other, charges accumulated in the photo diode PD may move to the first to third floating diffusion areas FD1 to FD3. Afterward, voltage levels of the first to third floating diffusion areas FD1 to FD3 may be sampled. Because charges are stored in a capacity (i.e., SD1+SD2+C) provided by the first to third floating diffusion areas FD1 to FD3, the relatively low conversion gain (LCG) may be provided.

In some example embodiments, in a second mode, charges, which are stored in the first floating diffusion area FD1, from among the charges stored in the first to third floating diffusion areas FD1 to FD3 may move to the second and third floating diffusion areas FD2 and FD3. For example, the first transmission signal TS1 may be at a low level, and the second transmission signal TS2 may be at a high level. Accordingly, the voltage level of the first floating diffusion area FD1 may be decreased by an overlap capacitor, and the voltage levels in the second and third floating diffusion areas FD2 and FD3 may be increased by the overlap capacitor. Accordingly, the asymmetric potential structure in which charges of the first floating diffusion area FD1 are capable of moving to the second and third floating diffusion areas FD2 and FD3 without loss or with reduced loss may be formed, and charges of the first floating diffusion area FD1 may move to the second and third floating diffusion areas FD2 and FD3. Afterward, voltage levels of the second and third floating diffusion areas FD2 and FD3 may be sampled. Because charges are stored in a capacity (i.e., SD2+C) provided by the second and third floating diffusion areas FD2 and FD3, a middle conversion gain (MCG) may be provided.

In some example embodiments, in a third mode, charges of the second floating diffusion area FD2 among the charge accumulated in the second and third floating diffusion areas FD2 and FD3 may move to the third floating diffusion area FD3. For example, the second transmission signal TS2 may be at a low level. Accordingly, the voltage level of the second floating diffusion area FD2 may be lowered by the overlap capacitor, and charges of the second floating diffusion area FD2 may move to the third floating diffusion area FD3. Afterward, the voltage level of the third floating diffusion area FD3 may be sampled. Because a sampling operation is performed by using only the charges stored in a capacity (i.e., C) provided by the third floating diffusion area FD3, the relatively high conversion gain (HCG) may be provided.

As described above, the unit pixel 112_2 according to some example embodiments of the present disclosure has an additional floating diffusion area and an additional floating diffusion transistor, thereby providing a wide dynamic range.

Meanwhile, the above description is an example. For example, the unit pixel 112_2 may include ‘k’ floating diffusion areas (′k′ is an integer greater than or equal to 2). In this case, the unit pixel 112_2 may include ‘k’ transfer transistors, and gate electrodes of the first to (k−1)-th transfer transistors among the ‘k’ transfer transistors may be formed to overlap the first to (k−1)-th floating diffusion areas when viewed in a horizontal direction, respectively. Accordingly, the scope of a dynamic range capable of being provided may be further widened.

[Image Sensor of Floating Diffusion Area Shared Structure]

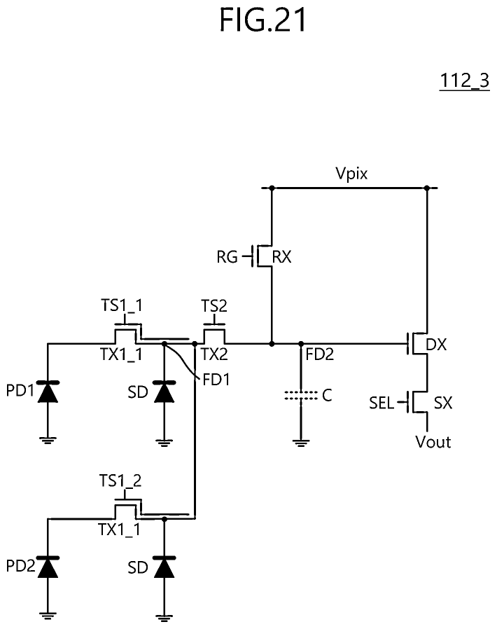

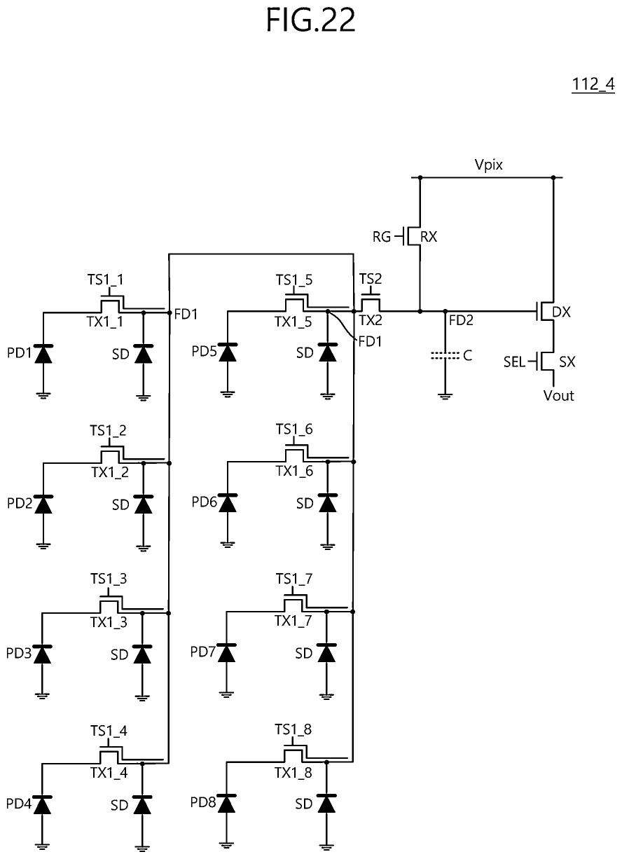

FIGS. 21 and 22 are circuit diagrams illustrating unit pixels 112_3 and 112_4, according to some example embodiments of the present disclosure. A structure of the unit pixel 112_3 or 112_4 of FIGS. 21 and 22 is similar to or the same as that of the unit pixel 112 of FIG. 2. Accordingly, the same or similar components are described by using the same or similar reference numerals, and redundant descriptions will be omitted below.

Referring to FIG. 21, the unit pixel 112_3 may include two photo diodes PD1 and PD2 and a plurality of NMOS transistors TX1_1, TX1_2, TX2, RX, DX, and SX.

Compared to the unit pixel 112 of FIG. 2, the unit pixel 112_3 of FIG. 21 has a structure in which two photo diodes share the same floating diffusion area with each other. In some example embodiments, FIG. 22 illustrates that eight photo diodes PD1 to PD8 share a floating diffusion area with one another.

In the case of a general floating diffusion area shared structure, a plurality of photo diodes are connected to the same floating diffusion area through corresponding transfer transistors, respectively. In other words, the floating diffusion area is connected to drains of the plurality of transfer transistors TX, and one end of the floating diffusion area is connected to a gate of the drive transistor DX. In this case, a parasitic capacitor may be generated between the floating diffusion area and gate electrodes of the plurality of transfer transistors TX. The capacity of a parasitic capacitor increases as the number of shared photo diodes increases, which operates as an obstacle to realize the high conversion gain (HCG) and to perform a high-sensitivity sampling operation.

To minimize or reduce the noise caused by the parasitic capacitor, the unit pixel 112_3 according to some example embodiments of the present disclosure may completely block a floating diffusion area, which is the target of sampling, from a gate electrode of the transfer transistor TX during a sampling operation of providing the high conversion gain (HCG). To the end, the unit pixel 112_3 according to some example embodiments of the present disclosure may have a structure including first and second floating diffusion areas FD1 and FD2, which are physically spaced from each other, and the second transfer transistor TX2 disposed therebetween.

As described above, after moving all the charges accumulated in the first floating diffusion area FD1 to the second floating diffusion area FD2, the unit pixel 112_3 according to some example embodiments of the present disclosure performs a sampling operation on only the second floating diffusion area FD2. Because the sampling operation is performed after the first floating diffusion area FD1 is separated from the second floating diffusion area FD2 through the second transfer transistor TX2, the noise caused by the parasitic capacitor between the first floating diffusion area FD1 and gates of the transfer transistors TX1_1 and TX1_2 may be minimized or reduced.

Besides, as described above, the charges may also move to the second floating diffusion area FD2 without loss or with reduced loss through the asymmetric potential structure using an overlap capacitor between the first floating diffusion area FD1 and gate electrodes of the first transfer transistors TX1_1 and TX1_2. As a result, the unit pixel 112_3 according to some example embodiments of the present disclosure may move charges generated by the photo diodes PD1 and PD2 to a node, at which a sensing operation is performed, without loss or with reduced loss and may provide high-sensitivity sampling having the high conversion gain (HCG).

Meanwhile, the number of photo diodes sharing the same floating diffusion area is not limited thereto. For example, as shown in FIG. 22, eight photo diodes PD1 to PD8 may have the same floating diffusion area. In this case, as described above, the noise caused by the parasitic capacitor between the first floating diffusion area FD1 and gates of transfer transistors TX1_1 to TX1_8 may be minimized or reduced, and the high conversion gain (HCG) may be provided.

The above description refers to detailed example embodiments for carrying out the present disclosure. Example embodiments in which a design is changed simply or which are easily changed may be included in the present disclosure as well as an example embodiment described above. In addition, technologies that are easily changed and implemented by using the above example embodiments may be included in the present disclosure. While the present disclosure has been described with reference to some example embodiments thereof, it will be apparent to those of ordinary skill in the art that various changes and modifications may be made thereto without departing from the spirit and scope of the present disclosure as set forth in the following claims.

An image sensor according to some example embodiments of the present disclosure may move charges, which are generated by a photo diode, in a direction of a node, at which a sensing operation is performed, without loss or with reduced loss. Accordingly, a high-quality image may be generated.

Any of the elements and/or functional blocks disclosed above may include or be implemented in processing circuitry such as hardware including logic circuits; a hardware/software combination such as a processor executing software; or a combination thereof. For example, the timing controller 150 may be implemented as processing circuitry. The processing circuitry specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

Processor(s), controller(s), and/or processing circuitry may be configured to perform actions or steps by being specifically programmed to perform those action or steps (such as with an FPGA or ASIC) or may be configured to perform actions or steps by executing instructions received from a memory, or a combination thereof.

While the present disclosure has been described with reference to some example embodiments thereof, it will be apparent to those of ordinary skill in the art that various changes and modifications may be made thereto without departing from the spirit and scope of the present disclosure as set forth in the following claims.

What is claimed is:

1. An image sensor comprising:
a plurality of first pixels arranged in a first row and configured to generate first charges in response to a first exposure; and
a plurality of second pixels arranged in a second row different from the first row and configured to generate second charges in response to a second exposure,
wherein at least one pixel of the plurality of first pixels includes
a photo diode configured to generate the first charges in response to the first exposure to an incident light,
a first floating diffusion area configured to store the first charges generated by the photo diode,
a first transfer transistor configured to electrically connect the photo diode to the first floating diffusion area in response to a first transmission signal, wherein a gate electrode of the first transfer transistor at least partially overlaps the first floating diffusion area in a horizontal direction,
a second floating diffusion area spaced apart from the first floating diffusion area, wherein one end of the second floating diffusion area is electrically connected to a gate of a drive transistor, and
a second transfer transistor configured to electrically connect the first floating diffusion area to the second floating diffusion area in response to a second transmission signal.

2. The image sensor of claim 1, further comprising a timing controller configured to cause the first transfer transistor to be turned off before the second transfer transistor is turned off.

3. The image sensor of claim 1, further comprising a timing controller configured to cause, while the first transfer transistor is turned on, the second transmission signal to transition from a low level to a high level, and thus the first charges stored in the first floating diffusion area to be shared and stored in the first floating diffusion area and the second floating diffusion area.

4. The image sensor of claim 3, wherein the timing controller is further configured to cause, while the second transfer transistor is turned on, the first transmission signal to transition from the high level to the low level, and thus the first charges shared in the first floating diffusion area and the second floating diffusion area to move in a direction of the second transfer transistor and the second floating diffusion area.

5. The image sensor of claim 4, wherein the timing controller is further configured to cause, while the first transfer transistor is turned off, the second transmission signal to transition from a high level to a low level, and thus the first charges present in a channel of the second transfer transistor to move to the second floating diffusion area.

6. The image sensor of claim 1, further comprising a timing controller configured to cause, while the second transfer transistor is turned on, the first transmission signal to transition from a low level to a high level, and thus the first charges generated by the photo diode to move to the first floating diffusion area and the second floating diffusion area.

7. The image sensor of claim 6, wherein, the timing controller is further configured to cause, while the second transfer transistor is turned on, the first transmission signal to transition from the high level to the low level, and thus a sampling operation is performed on the first floating diffusion area and the second floating diffusion area.

8. The image sensor of claim 1, further comprising a timing controller configured to cause,
while the first transfer transistor is turned off, the second transmission signal to transition from a low level to a high level, and thus the first floating diffusion area and the second floating diffusion area to be electrically connected to each other,
then, the first transmission signal to transition from a low level to a high level, and thus the first charges generated by the photo diode to be stored in the first floating diffusion area and the second floating diffusion area, and
then, a sampling operation to be performed on the first floating diffusion area and the second floating diffusion area.

9. The image sensor of claim 8, wherein, the timing controller is further configured to cause,
after the sampling operation is performed on the first floating diffusion area and the second floating diffusion area, the second transmission signal to transition from the high level to the low level, and thus the first charges stored in the first floating diffusion area and the second floating diffusion area to move to the second floating diffusion area, and
then, the sampling operation to be performed on the second floating diffusion area.

10. The image sensor of claim 1, wherein the at least one pixel of the plurality of first pixels further comprises:
a third floating diffusion area positioned between the first floating diffusion area and the second floating diffusion area and spaced from the first floating diffusion area and the second floating diffusion area; and
a third transfer transistor configured to electrically connect the first floating diffusion area to the third floating diffusion area,
wherein a gate electrode of the third transfer transistor overlaps the third floating diffusion area in the horizontal direction.

11. The image sensor of claim 1, wherein the at least one pixel of the plurality of first pixels further comprises:
a boosting capacitor connected to the first floating diffusion area.

12. The image sensor of claim 11, further comprising a timing controller configured to cause, in response to the first transmission signal transitioning from a low level to a high level, a positive voltage to be provided to the boosting capacitor.

13. The image sensor of claim 11, further comprising a timing controller configured to cause, in response to the first transmission signal transitioning from a high level to a low level, a negative voltage to be provided to the boosting capacitor.

14. The image sensor of claim 1, wherein the gate electrode of the first transfer transistor includes a first gate electrode portion and a second gate electrode portion, which are physically spaced from each other,
wherein the first gate electrode portion overlaps the photo diode in the horizontal direction, and
wherein the second gate electrode portion overlaps the first floating diffusion area in the horizontal direction.

15. The image sensor of claim 1, wherein the gate electrode of the first transfer transistor includes a first area corresponding to the photo diode and a second area corresponding to the first floating diffusion area, and
wherein the second area has a concave-convex structure.

16. An operating method of an image sensor operating in a rolling shutter scheme, the method comprising:
delivering charges generated by a photo diode to a first floating diffusion area, which overlaps a gate electrode of a first transfer transistor in a horizontal direction, by turning on the first transfer transistor;
while the first transfer transistor is turned on, sharing the charges stored in the first floating diffusion area with a second floating diffusion area by turning on a second transfer transistor;
moving the charges stored in the first floating diffusion area to the second transfer transistor and the second floating diffusion area by turning off the first transfer transistor;
moving the charges stored in the second transfer transistor to the second floating diffusion area by turning off the second transfer transistor; and
sampling a voltage level of the second floating diffusion area.

17. The method of claim 16, wherein a boosting capacitor is connected to the first floating diffusion area, and
wherein, when the first transfer transistor is turned on, a positive voltage is provided to the boosting capacitor.

18. The method of claim 16, wherein a boosting capacitor is connected to the first floating diffusion area, and
wherein, when the first transfer transistor is turned off, a negative voltage is provided to the boosting capacitor.

19. The method of claim 16, wherein the first transfer transistor is turned off before the second transfer transistor.

20. An operating method of an image sensor operating in a rolling shutter scheme, the method comprising:
electrically connecting a first floating diffusion area and a second floating diffusion area by turning on a second transfer transistor;
while the second transfer transistor is turned on, delivering charges generated by a photo diode to the first floating diffusion area and the second floating diffusion area, which are electrically connected to each other by turning on a first transfer transistor;
while the second transfer transistor is turned on, turning off the first transfer transistor; and
sampling a voltage level of the first floating diffusion area and the second floating diffusion area, which are electrically connected to each other.
